(19) United States
(12) Patent Application Publication
(10) Pub. No.: US 2012/0197442 A1
(43) Pub. Date: Aug. 2, 2012

(54) METHOD AND APPARATUS FOR IMPROVING SHOCK RESISTANCE OF MEMS STRUCTURES

(75) Inventors: HUIKAI XIE, Gainesville, FL (US); Karl R. Zawoy, High Springs, FL (US)

(73) Assignee: UNIVERSITY OF FLORIDA RESEARCH FOUNDATION INC., GAINESVILLE, FL (US)

(21) Appl. No.: 13/359,282

(22) Filed: Jan. 26, 2012

Related U.S. Application Data
(60) Provisional application No. 61/436,496, filed on Jan. 26, 2011.

(51) Int. Cl. G05D 3/00; H01L 41/00; H02N 11/00; G02B 7/198; G02B 7/02

(52) U.S. Cl. 700/275; 359/872; 359/822; 310/300; 310/311

(57) ABSTRACT

Embodiments of the subject invention relate to a method and apparatus for stabilizing a moveable element of a device. In an embodiment, a device is provided including a base, an element capable of moving relative to the base, and at least one actuator. Each actuator of the at least one actuator is configured such that when the actuator is driven the actuator moves into a hold position, wherein the actuator limits movement of the element. In a particular embodiment, the at least one actuator holds the element, or a portion of the element, at a particular position, angle, and/or attitude. In an embodiment, the at least one actuator is used to limit movement of the element when the device is turned off. The at least one actuator can be positioned to allow greater movement of the element when the device is turned on.

### CROSS-REFERENCE TO RELATED APPLICATION SECTION

The present application claims the benefit of U.S. Provisional Application Ser. No. 61/436,496, filed Jan. 26, 2011, which is hereby incorporated by reference herein in its entirety, including any figures, tables, or drawings.

### STATEMENT REGARDING FEDERALLY SPONSORED RESEARCH OR DEVELOPMENT

The subject invention was made with government support under National Science Foundation Contract No. ECCS0725598. The government has certain rights to this invention.

### BACKGROUND OF INVENTION

MEMS structures such as micromirrors, portable displays, and pico-projectors have been developed for use in medical imaging, optical communications, and other applications. It is estimated that the pico-projector market alone will reach 30 million units by 2012. All these devices may experience vibration, shaking, and/or sudden impacts, for example from being dropped, that may harm the structures. It is desired that medical devices can survive a 5-foot dropping onto a hard floor. This is a big challenge for fragile MEMS structures, especially MEMS structures with large movable ranges. Thus an apparatus and method for stabilizing MEMS structures and other structures is needed.

### BRIEF SUMMARY

Embodiments of the subject invention relate to a method and apparatus for stabilizing a moveable element of a device. In an embodiment, a device is provided including a base, an element capable of moving relative to the base, and at least one actuator. In a specific embodiment, each actuator of the at least one actuator is configured such that when the actuator is driven the actuator moves towards the element. In alternative embodiments, one or more of the at least one actuators can move away from the element when the one or more actuators are driven. When the at least one actuator moves towards the element, the at least one actuator can limit the movement of the element relative to the base. In a particular embodiment, the at least one actuator holds the element, or a portion of the element, at a particular position, angle, and/or attitude. In another specific embodiment, the at least one actuator confines the element to a range of locations. In a further embodiment, the at least one actuator can also be driven to recede from the element in order to allow greater movement of the element. In further embodiments, the actuators can incorporate hold elements that restrict movement of the element when the element is in a hold position or starts to move from the hold position.

Actuators can be used to limit the movement of a moving element at various times and for various purposes. For example, such actuators can be used to prevent damage to the moving element when it is not being used. In a particular embodiment, when a signal is received to turn the device off actuators are driven to brace the moving element. The actuators can then be driven to retract when a signal is received to turn the device on. The actuators can also be used during operation of the device. For example, when a desired position, angle, and/or attitude is reached the actuators can be used to maintain the position, angle, and/or attitude. In a particular embodiment, a signal is received from a user or other interface indicating when the actuators should be driven to contact or retract from the moving element. In other embodiments, the actuators do not necessarily contact the moving element. For example, the actuators can be used to prevent movement of the element beyond established parameters. Thus, a user or program can direct movement of the element within the established parameters without concern that the moving element will exceed the parameters. The parameters can be established for safety, operational, or other reasons.

### BRIEF DESCRIPTION OF DRAWINGS

FIG. 1 is an image of an embodiment of a Micro-Electro-Mechanical System (MEMS) micromirror.

FIGS. 2A-2B show an apparatus for improving shock resistance of a micromirror in accordance with an embodiment of the subject invention, wherein FIG. 2A shows the apparatus in an open position in which the mirror plate is free to move and FIG. 2B shows the apparatus in a closed position in which movement of the mirror plate is limited.

FIGS. 3A-3B show apparatus for improving shock resistance of MEMS in accordance with two embodiments of the subject invention.

FIG. 4 shows a cross-sectional area of a bimorph in accordance with an embodiment of the subject invention.

FIGS. 5A-5H show various MEMS structures having elements that can be stabilized in accordance with embodiments of the subject invention.

FIGS. 6A-6D show additional MEMS structures having elements that can be stabilized in accordance with embodiments of the subject invention.

FIGS. 7A-7J show further MEMS structures having elements that can be stabilized in accordance with embodiments of the subject invention.

### DETAILED DISCLOSURE

Embodiments of the subject invention relate to a method and apparatus for stabilizing a moveable element of a device. In an embodiment, a device is provided including a base, an element capable of moving relative to the base, and at least one limiting actuator. The limiting actuator(s) can be referred to as a hold element, where the hold element can be an actuator and/or incorporate an actuator. In a specific embodiment, each limiting actuator is configured such that when the actuator is driven the actuator limits movement of the moving element. In another embodiment, different subsets of the at least one limiting actuator are used at different times. In an embodiment, at least two limiting actuators are used. In a further embodiment, three or more limiting actuators are used.

Movement of a moveable element can be limited and/or restricted in various ways. In a particular embodiment, the at least one actuator holds the element, or a portion of the element, at a particular position, angle, and/or attitude. In a further embodiment, at least one actuator can be driven so as to hold the element, or a portion of the element, at a plurality of positions, angles, and/or attitudes (e.g., initial position, raised position, lowered position, tilted position, etc.). In another embodiment, a plurality of sets of actuators is used to hold the actuator at a corresponding plurality of positions, angles, and/or attitudes. In another embodiment, the at least one actuator only allows the element to move or turn a particular distance in a direction. For example, the at least one actuator can prevent the element from moving down more than 100 microns. Additional embodiments can prevent the element from moving down more than 50 microns, down more than 40 microns, down more than 30 microns, down more than 20 microns, down more than 10 microns, down more than 5 microns, up more than 100 microns, up more than 50 microns, up more than 40 microns, up more than 30 microns, up more than 20 microns, up more than 10 microns, up more than 50 microns, up or down more than 100 microns, up or down more than 50 microns, tip or down more than 40 microns, up or down more than 30 microns, up or down more than 20 microns, up or down more than 10 microns, and/or up or down more than 5 microns. In a further embodiment, movement is limited in multiple dimensions. In an embodiment, movement is restricted to one or more established positions, angles, and/or attitudes. In an embodiment, movement is restricted to a range of positions, angles, and/or attitudes. In an embodiment, the element is held and/or kept a safe distance away from other components of the device. Other limits on the movement of the element can also be accomplished. In specific embodiments, the range of motion of the element when the hold element, or actuator, is in a free position such that the hold element is not limiting the motion of the element, is 100 microns in a first direction, such as the vertical direction, 90 microns in a first direction, 80 microns in a first direction, 70 microns in a first direction, 60 microns in a first direction, or 50 microns in a first direction. In a further embodiment, the separation between the hold element and the element in the first direction is less than or equal to 10 microns, 9 microns, 8 microns, 7 microns, 6 microns, 5 microns, 4 microns, 3 microns, 2 microns, 1 micron, and/or 0 microns.

Actuators can be used to limit the movement of a moving element at various times and for various purposes. For example, such actuators can be used to prevent damage to the moving element when it is not being used. In a particular embodiment, when a signal is received to turn the device off actuators are driven to brace the moving element. The actuators can then be driven to retract or otherwise free the moving element when a signal is received to turn the device on. In order to conserve power, the actuators can be configured such that they are in a bracing position when unpowered and retract when the device is turned on and power is directed to the actuators. The actuators can also be used during operation of the device. For example, when a desired position, angle, and/or attitude is reached the actuators can be used to maintain the position, angle, and/or attitude. In a particular embodiment, a signal is received from a user or other interface indicating when the actuators should be driven to limit or free the moving element. In embodiments, the actuators do not necessarily contact the moving element. For example, the actuators can be used to prevent movement of the element beyond established parameters. Thus, a user or program can direct movement of the element within the established parameters without concern that the moving element will exceed the parameters. The parameters can be established for safety, operational, or other reasons. In an embodiment, the parameters are pre-established. In a further embodiment, the parameters can be adjusted during operation of the device.

In an embodiment, an apparatus is provided incorporating a base, a movable element movably connected to the base, and at least one hold element, wherein the hold element is configured to limit or restrict the movement of the moveable element. The hold element can be positioned in various ways to achieve this limitation or restriction. In an embodiment, the hold element is moveably connected to the base or another surface such that it can transition from a hold position, wherein it limits or restricts movement of the moveable element, to one or more free positions, wherein movement of the moveable element is less limited or restricted. Additional hold element positions can also be achieved in order to limit or restrict the movement of the moveable element in different ways. In an embodiment, the hold element is moveably connected to the base via one or more hold element actuators, wherein the hold element actuators can be driven to transition the hold element between various hold element positions.

In an embodiment of the subject invention, the moveable element is positioned in one or more moveable element hold positions where it can be held or restricted by the at least one hold element. The apparatus can incorporate moveable element actuators configured to transition the moveable element between various moveable element positions, including the one or more movable element hold positions. In a particular embodiment, the moveable element is connected to the base or another surface via the movable element actuators, wherein the one or more movable element actuators can be driven to transition the moveable element between the various moveable element positions.

In a further embodiment of the subject invention, the apparatus incorporates a controller configured to receive one or more signals to drive one or more hold element actuators to cause movement of a hold element in response to such signals. In an embodiment, the controller is also configured to drive one or more moveable element actuators to cause movement of a moveable element in response to such signals. In an embodiment, when the controller receives an off signal the controller transitions the apparatus to a parked condition wherein the movement of the moveable element is limited. In a particular embodiment, after receiving the off signal the controller drives one or more hold element actuators to position at least one hold element in a hold element hold position. The controller can also drive one or more movable element actuators to transition a moveable element to a moveable element hold position. In a further embodiment, the controller is also be configured to process and respond to movement signals directing movement of the moveable element. In an embodiment, the controller processes these movement signals differently when the apparatus is in a parked condition and/or the movement of the moveable element is limited by a hold element. For example, the controller can be configured to ignore the movement signals when the apparatus is in a parked condition. Or the controller can be configured to achieve a free condition, in which the hold element no longer limits movement of the moveable element, before proceeding to cause movement of the moveable element. In an embodiment, the controller automatically transitions the apparatus to the free condition when the apparatus is turned on or an on signal is otherwise received by the controller.

Various other moveable element positions and/or conditions can be maintained. For example, hold elements can limit the moveable element to various positions, angles, and/or attitudes or ranges of positions, angles, and/or attitudes. In an embodiment, the controller can be used to position the moveable element and/or the hold elements so as to achieve and/or maintain different desired positions, angles, and/or attitudes at different times. The controller can receive different signals directing the apparatus to achieve and/or maintain the different positions, angles, and/or attitudes. In an embodiment, various positions, angles, and/or attitudes, ranges of positions, angles, and/or attitudes, or other limitations can be established, by programming them into the controller or other media. In a further embodiment, such limitations can also be established or varied during operation of the apparatus. In an embodiment, the controller is configured to receive signals establishing or varying such limitations.

The subject invention can be applied to various devices incorporating various moving elements. In a particular embodiment, the device incorporates a base and a mirror affixed to a mirror plate and the actuators limit the movement of the mirror plate relative to the base. Thus in an embodiment, opportunity for damage to the mirror, or other element, is lessened when the mirror is not in use. The subject invention can also be applied to limit the movement of a lens holder holding a lens. The examples given here are illustrative. The subject invention can also be applied to other devices. In an embodiment, the invention is applied to Micro-Electro-Mechanical Systems (MEMS). In another embodiment, the invention is applied to larger devices. These and other types of devices are further described in U.S. patent application Ser. No. 12/534,514, filed Aug. 3, 2009 and published as U.S. 2010/0033788, U.S. patent application Ser. No. 12/743,499, filed May 18, 2010 and published as U.S. 2010/0307150, and International Patent Application No. PCT/US2010/036925, filed Jun. 1, 2010 and published as WO 2010/138968, which are incorporated by reference herein in their entirety.

Various types of actuators can be used to limit movement of the moving element. For example, bimorph, multimorph, bistable thermal, shape memory alloy, and/or piezoelectric actuators can be used. This list is illustrative; other types of actuators known in the art can be used with the subject invention. In an embodiment, a lateral bimorph actuator is used. In a particular embodiment, the lateral bimorph actuator has an asymmetrical cross-section such that when the lateral bimorph actuator is driven it moves in multiple dimensions. In an embodiment, an actuator is used that incorporates a shape memory alloy (SMA). When heat is applied to the SMA, the shape of the material changes. When the heat dissipates, the material returns to its original shape. In a particular embodiment, such an actuator is configured such that it is in a bracing position when unheated and retracts when heat is applied. These and other types of actuators are further described in U.S. patent application Ser. No. 12/534,514, filed Aug. 3, 2009 and published as U.S. 2010/0033788, U.S. patent application Ser. No. 12/743,499, filed May 18, 2010 and published as U.S. 2010/0307150, and International Patent Application No. PCT/US2010/036925, filed Jun. 1, 2010 and published as WO 2010/138968, which are incorporated by reference herein in their entirety.

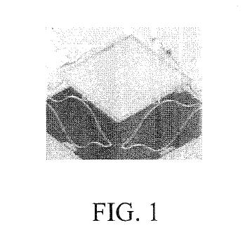

In a particular embodiment of the subject invention, one or more actuators are used to limit the swing of a mirror plate incorporated into a micromirror device. An example of such a micromirror device is shown in FIG. 1. As shown in FIG. 1, the mirror plate is elevated, providing space for large-range rotation and piston. However, the large gap also provides space for excessive swing of the mirror plate upon a shock, which may damage or even break the suspension flexures, resulting in reduced lifetime or complete failure. In an embodiment, the actuators hold the mirror plate when the mirror is not scanning and/or the device is powered off.

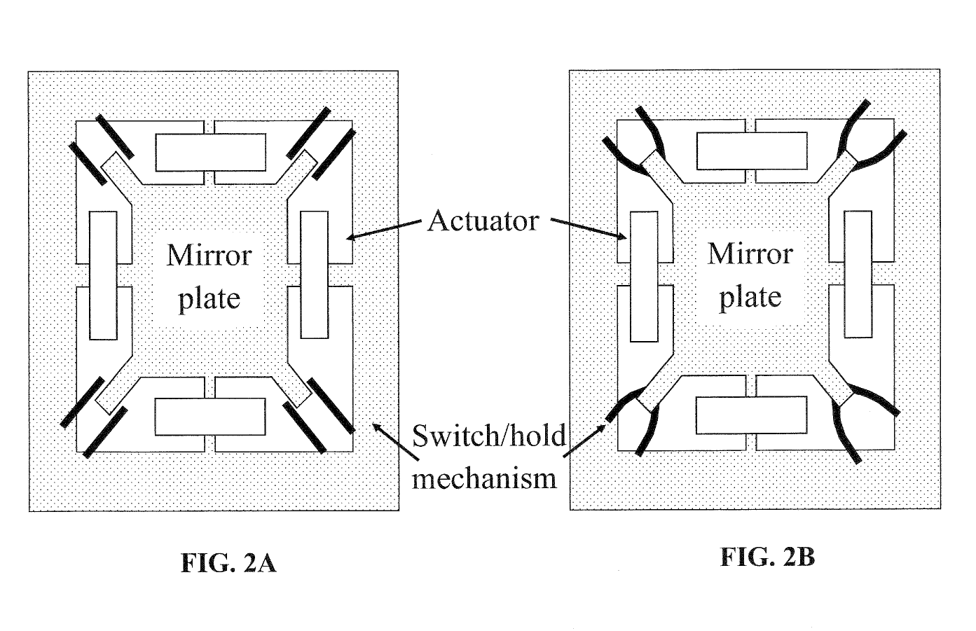

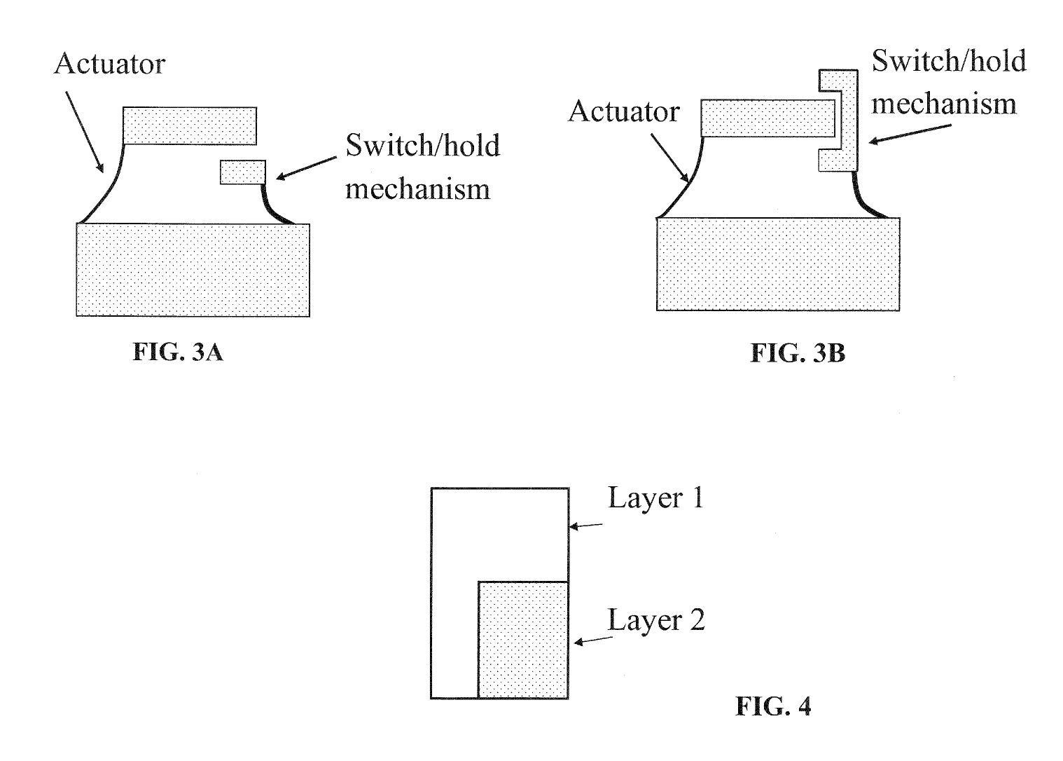

Various actuator configurations can be used to hold and/or limit movement of the mirror plate. A few example embodiments are shown in FIGS. 2A-2B and 3A-3B. These examples are illustrative; other embodiments are possible. The actuators can be retracted from the mirror plate during scanning and used to hold and/or limit the movement of the mirror plate when scanning is complete and/or the device is turned off. In a further embodiment, the actuators can also be used during operation of the device. For example, the actuators can be used to prevent the movement of the mirror plate beyond certain established parameters. Actuators can also be used to hold the mirror plate in a desired position, angle, and/or attitude.

FIGS. 2A-2B depict an embodiment using four switch/hold mechanisms, to hold a mirror plate. In the embodiment shown, each switch/hold mechanism incorporates two actuators, or hold elements, which move towards each other to hold the mirror plate at its corners by contacting the corners of the mirror plate so as to hold the corners of the mirror plate. In this way, contact by the hold elements in a second direction prevents, or limits, movement in a first direction, where in the embodiment shown in FIGS. 2A-2B the first direction is perpendicular to the second direction. In the embodiment shown in FIGS. 2A-2B, the actuators or hold elements also prevent, or limit, movement in the second and third direction, where the third direction is perpendicular to both the first and second directions. More or fewer actuators can be used, and the actuators can contact the mirror plate or other moving element in other locations. In FIG. 2A, the switch/hold mechanisms are shown retracted from the mirror plate. In this configuration, the mirror plate is free to move. In the embodiment shown, the mirror plate can be moved using four actuators positioned around the mirror plate. In FIG. 2B, the switch/hold mechanisms are shown in contact with the mirror plate. In this configuration, movement of the mirror plate is limited. In a particular embodiment, when the mirror is in use, the switch/hold mechanisms are open (as shown in FIG. 2A) such that the mirror plate can move freely. At rest and/or power off, the switch/hold mechanisms can hold the mirror plate (as shown in FIG. 2B). In a further embodiment, the switch/hold mechanisms are used to limit movement of the mirror plate during operation. The switch/hold mechanisms can be positioned so as to contact the element at a desired height, or position in a first direction. Specific embodiments can utilize multiple hold elements at corresponding multiple positions in the same directions, for example to hold the mirror plate at a corresponding direction position, in the same direction.

FIGS. 3A-3B depict particular embodiments of a switch/hold mechanism. As shown in FIG. 3A, the switch/hold mechanism, or hold element, can be “single-sided” such that it contacts the mirror plate in one location. The switch/hold mechanism, or hold element, can also be “double-sided” as shown in FIG. 3B such that it can contact the mirror plate, or be positioned proximate the mirror plate, in two locations. In the specific embodiment shown in FIG. 3B the hold element is positioned above and below, and to the side of the mirror plate, so as to limit movement of the mirror plate up, down, or to one side. If 2, 3, or 4 hold elements are used on a corresponding 2, 3, or 4 sides, then the mirror plate can be prevented from, or limited in, movement in a corresponding 2, 3, or 4 directions in a plane of the mirror plate. Other configurations are possible wherein the switch/hold mechanism contacts the mirror plate in two, three or more locations. As shown in FIG. 3A, in embodiments the switch/hold mechanism can be configured such that when it is driven the mechanism pushes up on the mirror plate to hold the mirror plate in place. As shown in FIG. 3B, in embodiments the switch/hold mechanism can be configured such that when it is driven the mechanism pinches in on the mirror plate to hold the mirror plate in place. In a particular embodiment, when the mirror starts to scan, the switch/hold mechanisms are disengaged from the mirror plate such that the mirror plate is free to scan (see FIG. 2A). In an embodiment, the switch/hold mechanism incorporates at least one hold element positioned to limit movement of the mirror plate or other element. The hold element can contact the mirror plate or otherwise limit its movement. In an embodiment, a magnetic or electro-magnetic field can be used to limit movement of the mirror plate or other moveable element.

The hold element in FIG. 3A can come in from right of FIG. 3A to move to the hold position and move to the right to move to the free position, where the mirror plate is free to move. Alternatively, the hold element can move into or out of the plane of the figure to move into the hold position, and move in the opposite way to move to the free position.

Various actuators can be used to hold and/or limit the movement of the mirror plate or other element including bimorph, multimorph, bistable thermal, shape memory alloy, piezoelectric actuators, and/or other known actuators. In an embodiment, such actuators are used to position a hold element or are otherwise incorporated into a switch/hold mechanism. In a particular embodiment, a lateral bimorph actuator incorporating two different beam materials is used to achieve the lateral displacement required by the switch/hold mechanism. When a stimulus, such as heat, is applied to the actuator the different beam materials react differently thus changing the shape of the actuator. In a further embodiment, as shown in FIG. 4, the cross section of the actuator beams or layers has the second layer on top and at one side of the first layer. This configuration can achieve both vertical and lateral bending. FIG. 4 depicts an illustrative example; other nonsymmetrical multimorph configurations can be used to achieve movement in multiple dimensions.

A sensor can be incorporated such that when a certain magnitude shock, or acceleration, is experienced by the apparatus the hold elements are activated to move to the hold position.

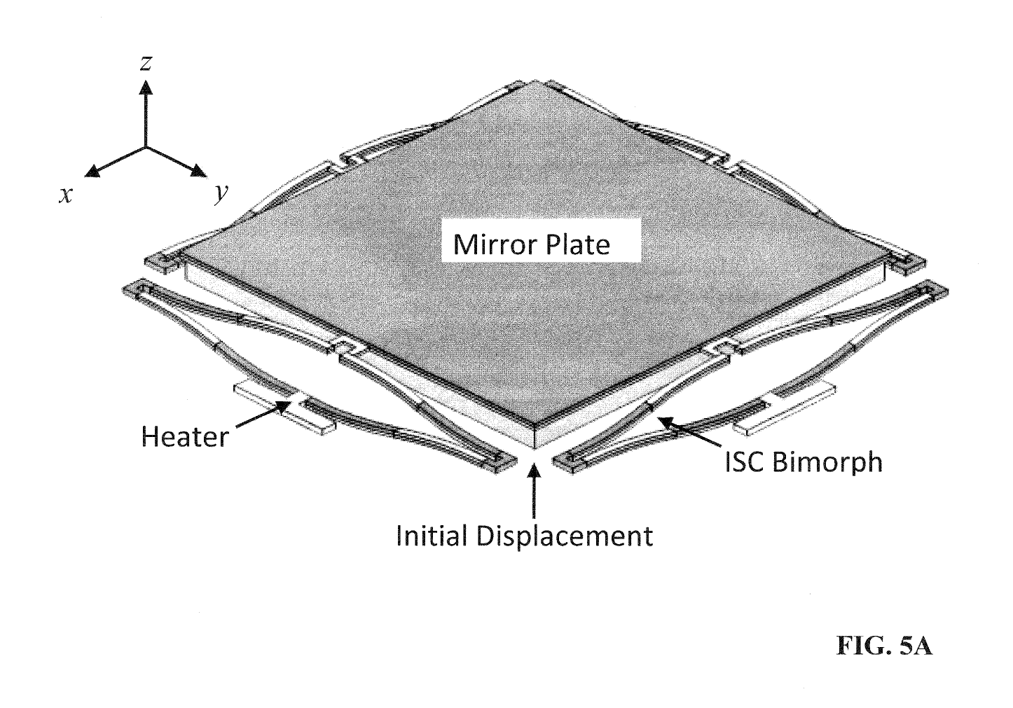

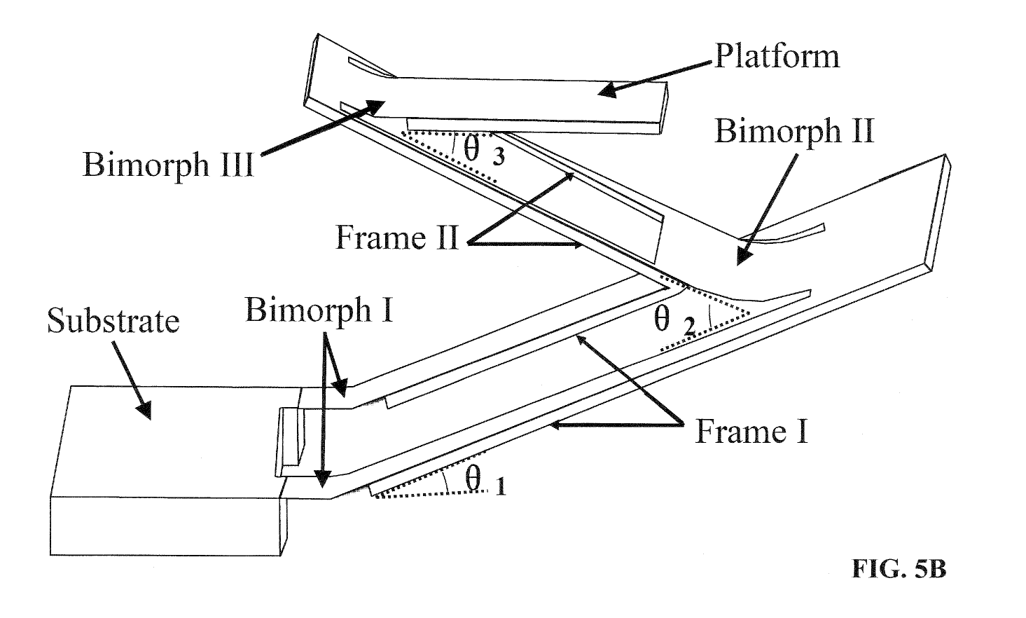

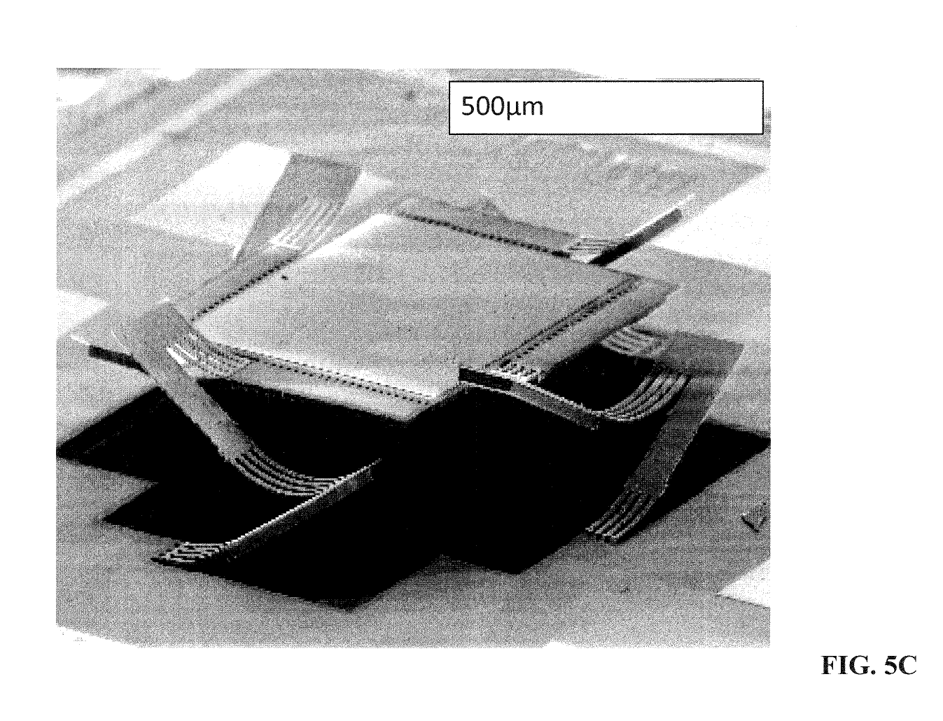

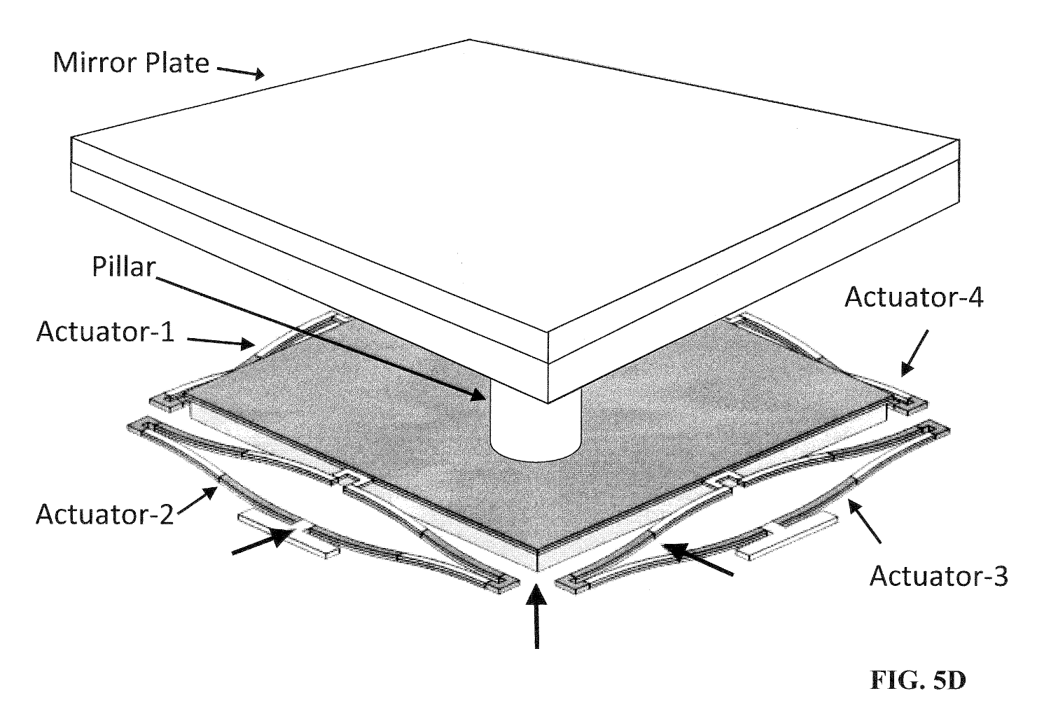

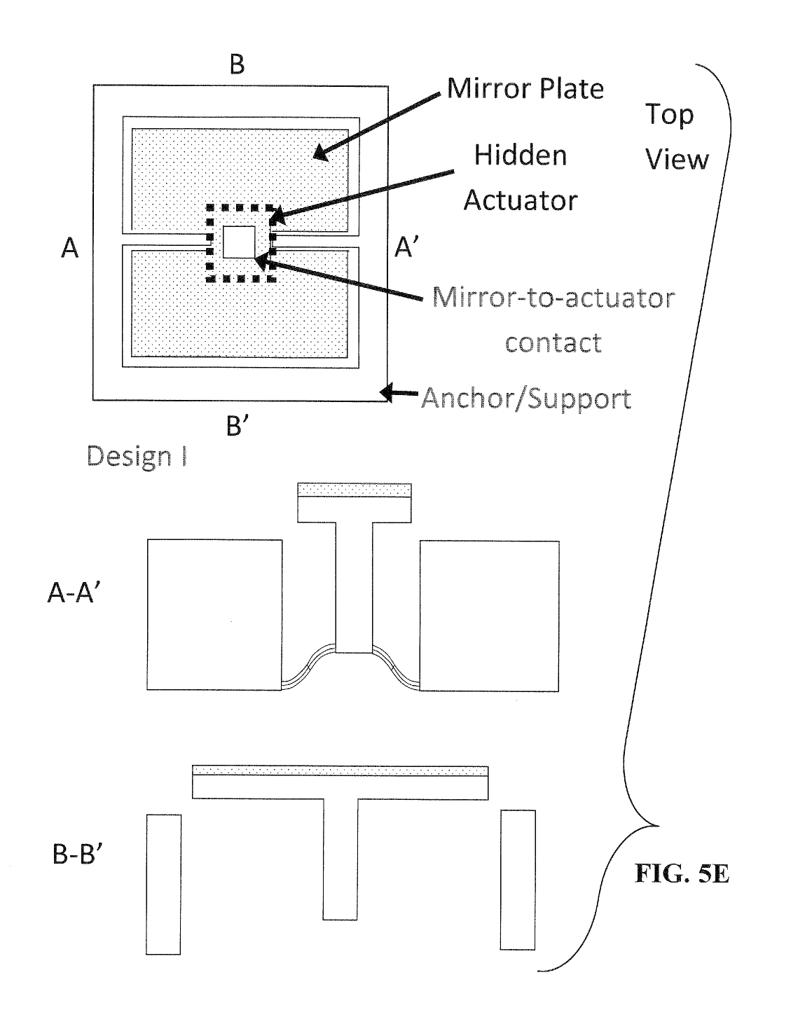

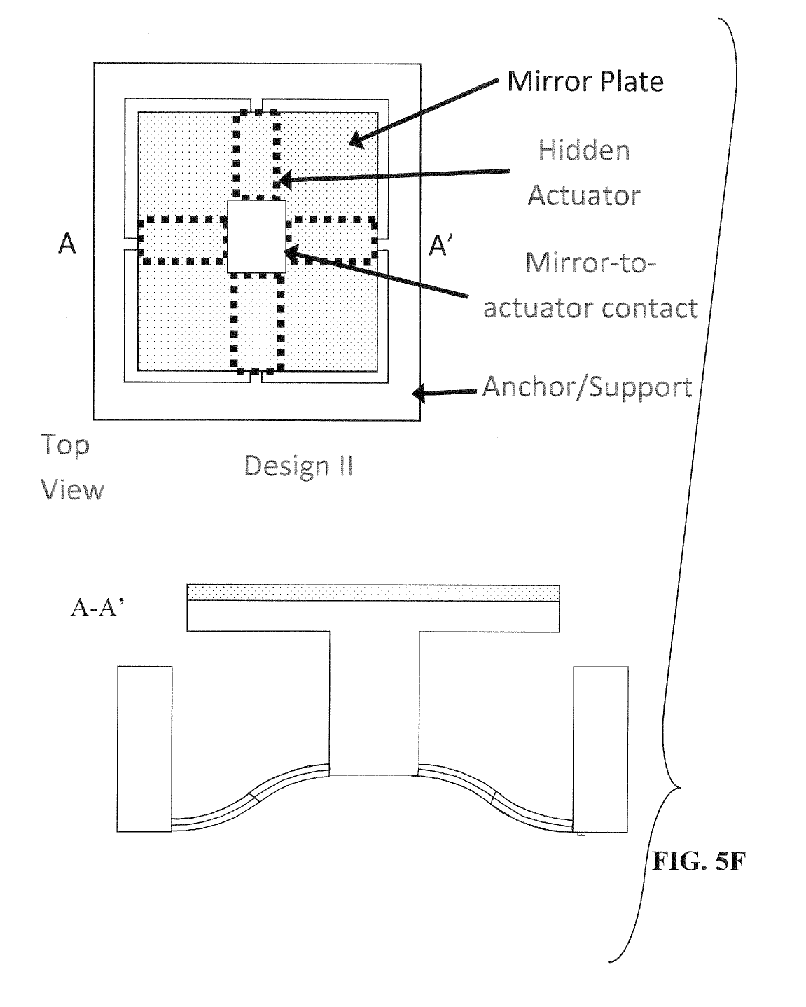

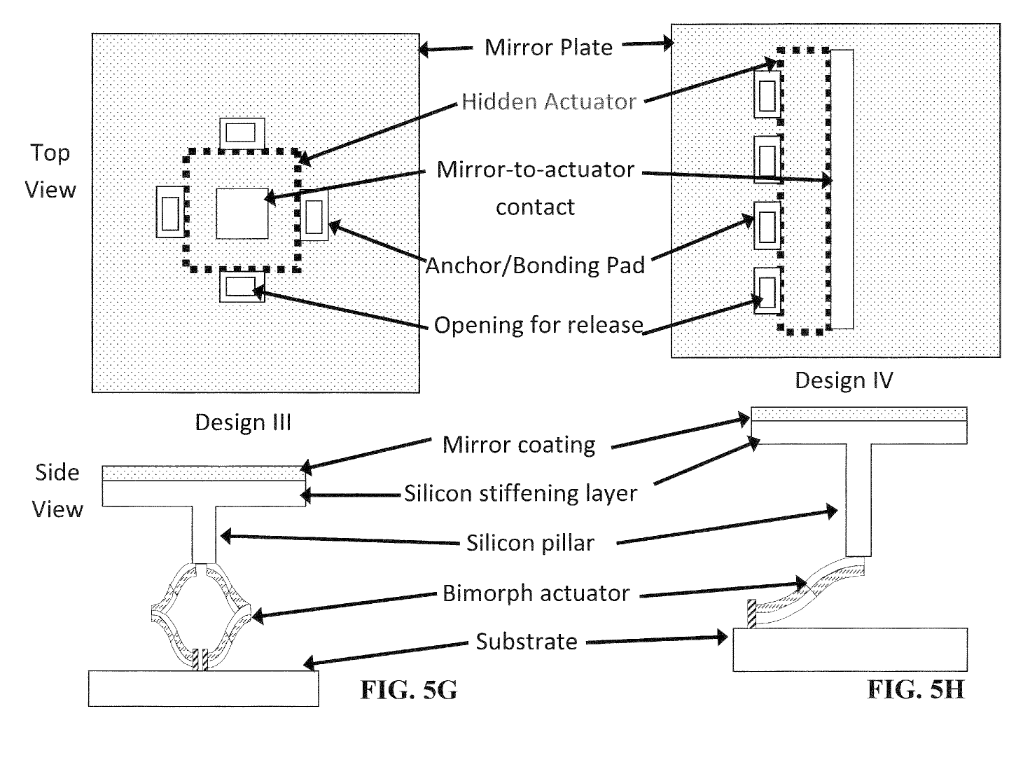

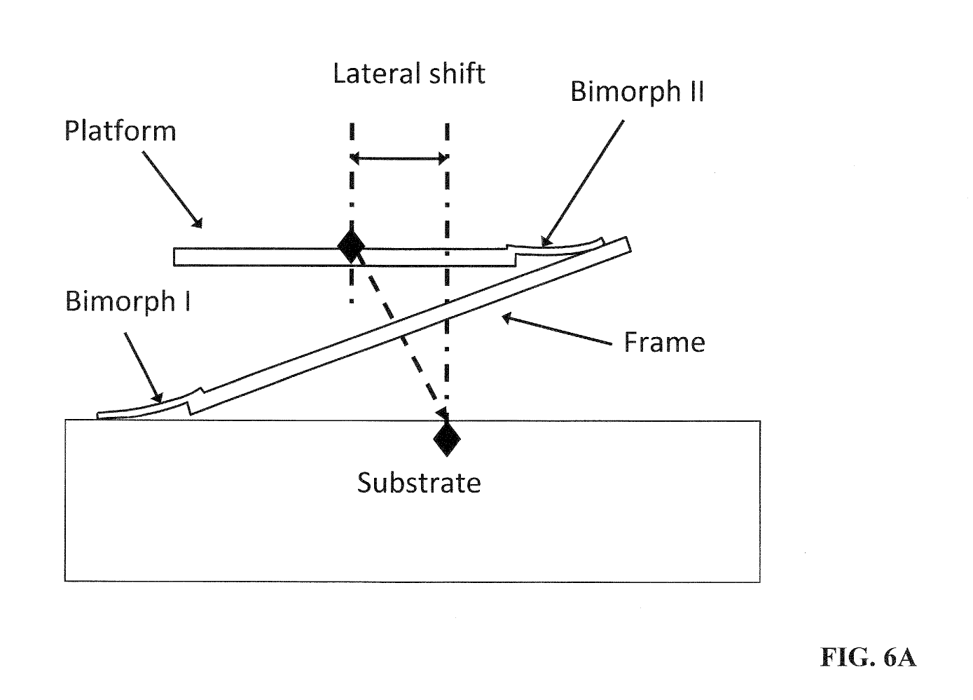

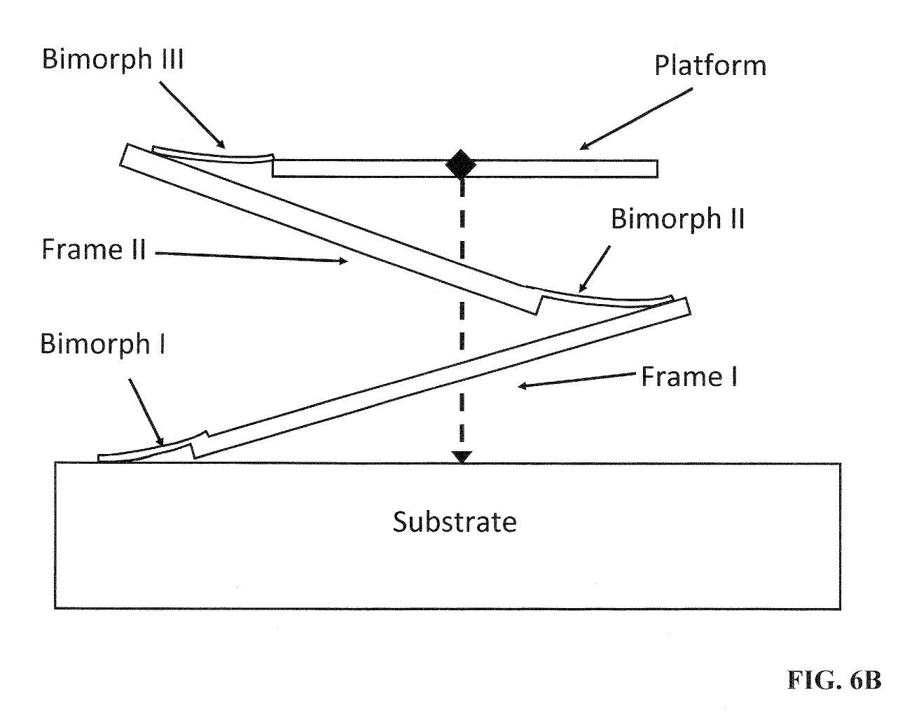

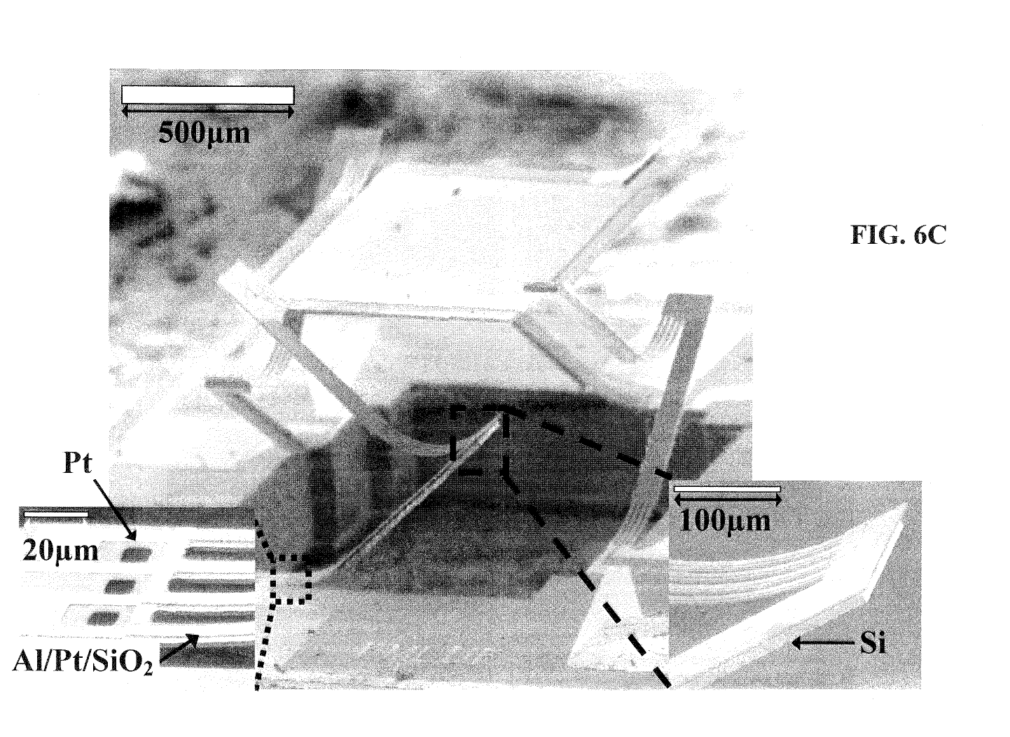

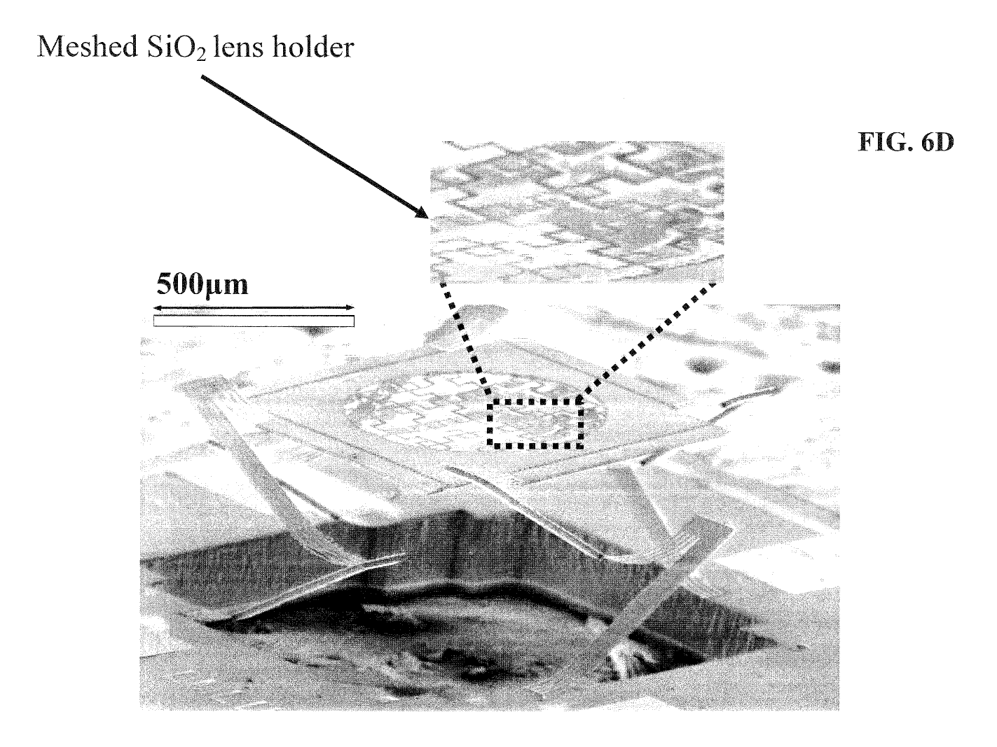

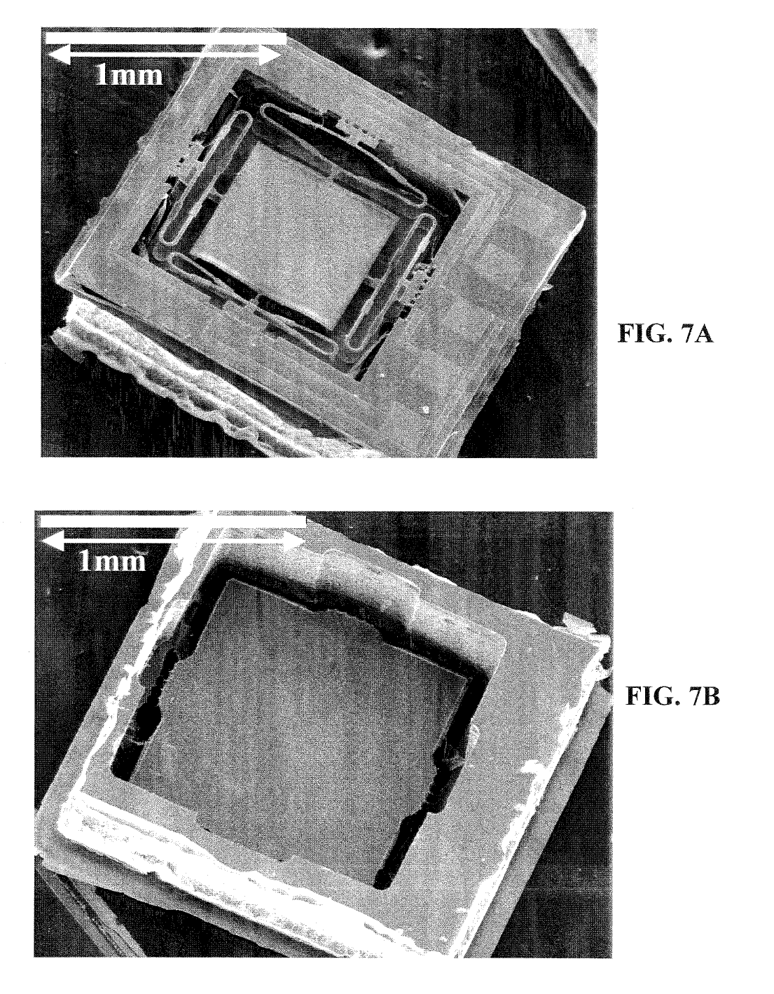

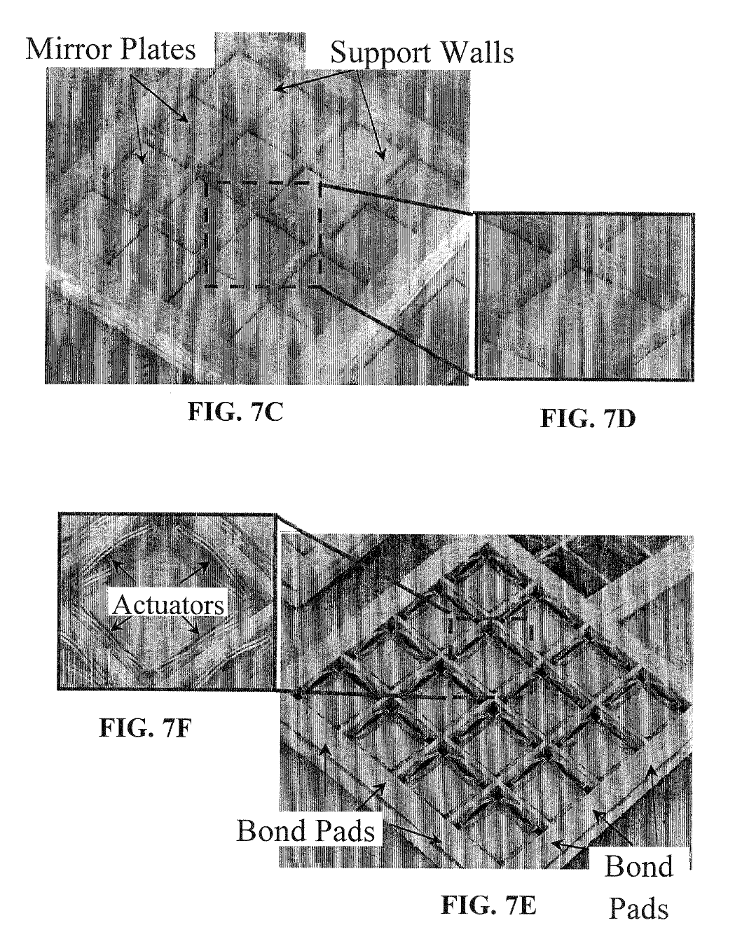

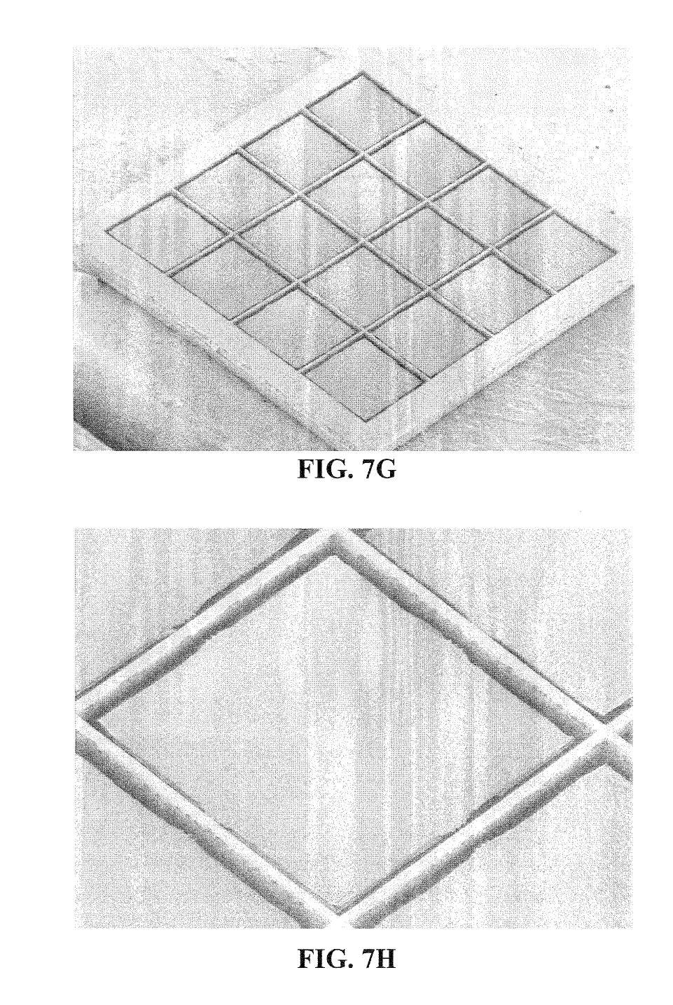

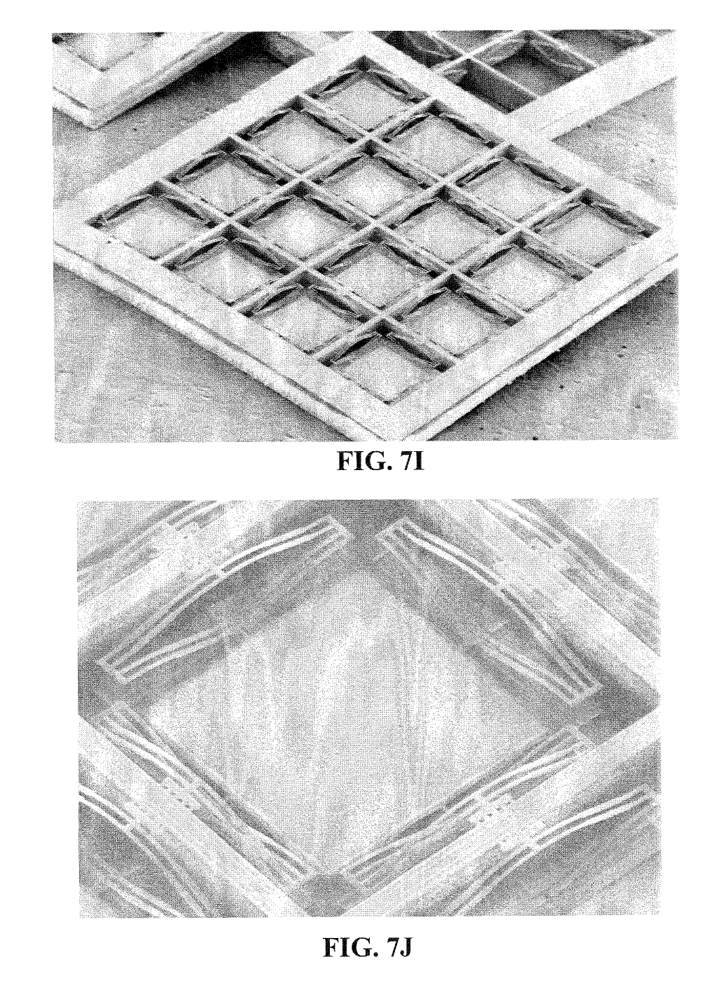

Various embodiments of the subject invention can be used to increase shock resistance, life time, and/or reliability of devices. Embodiments of the subject invention are particularly suited to stabilization of MEMS devices, especially large-displacement micromirrors. FIGS. 5A-5H show various MEMS structures having elements that can be stabilized in accordance with embodiments of the subject invention. These structures are further described in U.S. patent application Ser. No. 12/534,514, filed Aug. 3, 2009, which is incorporated by reference herein in its entirety. FIGS. 6A-6D show additional MEMS structures having elements that can be stabilized in accordance with embodiments of the subject invention. These structures are further described in U.S. patent application Ser. No. 12/743,499, filed May 18, 2010 and published as U.S. 2010/0307150, which is incorporated by reference herein in its entirety. FIGS. 7A-7J show further MEMS structures having elements that can be stabilized in accordance with embodiments of the subject invention. These structures are further described in International Patent Application No. PCT/US2010/036925, filed Jun. 1, 2010 and published as WO 2010/138968, which is incorporated by reference herein in its entirety. FIG. 8 of International Patent Application No. PCT/US2010/036925, published as WO 2010/138968, depicts a micromirror incorporated into a dental optical coherence tomography product. Such MEMS structures can also be incorporated into other products known in the art.

In an embodiment, a controller is used to drive actuators in response to received signals. For example, the controller can drive the actuators to stabilize a moving element when a rest and/or off signal is received. In another embodiment, the controller is used to drive the actuators to free the moving element when an on and/or movement signal is received. In an embodiment, the controller also controls actuators configured to move the moving element. When a signal is received to move the moving element, the controller can retract the stabilizing actuators before driving the other actuators to produce the desired movement.

Additional embodiments of the subject invention relate to a method and apparatus for compound imaging. In an embodiment, a plurality of MEMS structures, such as micromirrors, portable displays, pico-projectors, sensors, transducers, and/or input-output devices can be arranged on a curved surface, such as in a spherical, concave, or convex configuration, or on a planar surface. In a further embodiment, the plurality of MEMS structures can be configured to simulate a compound eye, similar to a fly eye.

In a specific embodiment, each MEMS structure can have a home and/or can fix its position on demand, such that an array of MEMS structures can, for example, operate as a complex imaging device, operate as a read/write data device, and/or operate to perform other useful purposes that may involve a micromirror incorporated into or with each MEMS structure. In specific embodiments, the array of MEMS structures can be operated with minimal power usage and processing overhead. Large arrays of MEMS structures in accordance with embodiments of the invention can be controlled via computer software and/or hardware.

In a specific embodiment, control of one or more large arrays can be accomplished using a Peer-to-Peer communication protocol. For example, as one row, or other subset, of MEMS elements, or controlling elements, move to a desired position, subsequent rows follow suit and move in unison. The subsequent rows can be programmed to mimic what the first row does with, for example, a time delay or immediately. This allows for the control of very large imaging and/or data reading/recording MEMS structures with minimal processing and control system overhead to maintain position.

Such Peer-to-Peer communication between the MEMS structures allows the large array of MEMS structures (or Fly-eye) to operate hundreds, thousands, or more elements in unison or other timing pattern. Each MEMS element can have an incremental off-set from the original row of controlling elements. In a specific embodiment, for an array of MEMS structures arranged in a hemispherical arrangement, or eye shape, the controlling elements can be located in a bulls-eye area at the center of the eye. Once the MEMS structures in the bulls-eye area focus on the subject, peer-to-peer commands are issued for all other elements to auto-align at the correct focal length using a predetermined off-set.

Additional functions can be incorporated with embodiments of arrays of MEMS structures, such as color vision, polarization sensitivity, and movement detection. Embodiments of arrays of MEMS structures can be used as an imaging system and can be integrated with task-specific image processing, such as artificial neural networks, to implement the desired task. An embodiment of an array of MEMS structures can produce results of a curved structure by having the bracing position, or home position of each MEMS structure be such that the MEMS structures are positioned on a curve when the MEMS structures are in the home position, even though the base on which the MEMS structures are positioned is a planar surface. Such a curved structure performance allows a large field of view, avoiding off-axis aberrations, and avoiding declining illumination with increasing field angle.

In further embodiments, MEMS devices and/or MEMS arrays in accordance with the subject invention can be utilized in a human-machine interface or an animal-machine interface. A human or animal can wear a single device or a pair of devices that function as a compound spectacle or a pair of compound glasses, respectively. The human-machine or animal-machine MEMS devices or MEMS arrays can also be used for enhanced functionality for a cybernetic interface. In a further embodiment, MEMS devices and/or MEMS arrays in accordance with the subject invention can be utilized with a biometric interface that uses a large MEMS array to exhibit human or animal surfaces. The surface can be very uniform when MEMS devices in accordance with the invention that have a bracing, or home, position, which can be referred to as Fixed Focus MEMS, are in the bracing, or home, position. The surface can then change uniformly when the subject MEMS or array of MEMS move in unison or with some predetermined temporal relationship. Human-machine or animal-machine interfaces in accordance with the subject invention can utilize small electrodes (10 μm) to stimulate small groups of nerve cells based on stimuli received at the MEMS device or MEMS array. A “closed-loop” system can measure signals from brain cells and use the signals received from the brain, after signals based on the stimuli received at the MEMS device or MEMS array are sent to the brain, in order to “steer”, or otherwise interact with, the applied stimuli.

A further embodiment involves the incorporation of MEMS devices or MEMS arrays in accordance with the invention into a contact lens either as a display and/or as a receiver, such that, for example, information can be provided to a wearer of the contact lens and/or information regarding the stimuli provided to the wearer of the contact lens can be gathered. Such display and/or receiver can interface with the eye. Contact lenses can incorporate one or more built-in LEDs, OLEDs, or other type of MEMS technology, which can be powered, for example, wirelessly with Radio Frequency and other simple electronic circuits. Contact lenses incorporating hundreds or more of tiny LEDs can display images, words, and other information in front of the eye, and can perform as a display for a separate control unit, such as a smartphone.

In an embodiment, one or more steps of a method for stabilizing an apparatus are preformed by one or more suitably programmed computers. In a particular embodiment, at least one of the receiving or driving steps is preformed by the one or more suitably programmed computers. Computer-executable instructions for performing these steps can be embodied on one or more computer-readable media as described below. In an embodiment, the one or more suitably programmed computers incorporate a processing system as described below. In an embodiment, the one or more suitably programmed computers incorporate a controller as described above.

Aspects of the invention can be described in the general context of computer-executable instructions, such as program modules, being executed by a computer. Generally, program modules include routines, programs, objects, components, data structures, etc., that perform particular tasks or implement particular abstract data types. Such program modules can be implemented with hardware components, software components, or a combination thereof. Moreover, those skilled in the art will appreciate that the invention can be practiced with a variety of computer-system configurations, including multiprocessor systems, microprocessor-based or programmable-consumer electronics, minicomputers, mainframe computers, and the like. Any number of computer-systems and computer networks are acceptable for use with the present invention.

Specific hardware devices, programming languages, components, processes, protocols, formats, and numerous other details including operating environments and the like are set forth to provide a thorough understanding of the present invention. In other instances, structures, devices, and processes are shown in block-diagram form, rather than in detail, to avoid obscuring the present invention. But an ordinary-skilled artisan would understand that the present invention can be practiced without these specific details. Computer systems, servers, work stations, and other machines can be connected to one another across a communication medium including, for example, a network or networks.

As one skilled in the art will appreciate, embodiments of the present invention can be embodied as, among other things: a method, system, or computer-program product. Accordingly, the embodiments can take the form of a hardware embodiment, a software embodiment, or an embodiment combining software and hardware. In an embodiment, the present invention takes the form of a computer-program product that includes computer-useable instructions embodied on one or more computer-readable media. Methods, data structures, interfaces, and other aspects of the invention described above can be embodied in such a computer-program product.

Computer-readable media include both volatile and nonvolatile media, removable and nonremovable media, and contemplate media readable by a database, a switch, and various other network devices. By way of example, and not limitation, computer-readable media incorporate media implemented in any method or technology for storing information. Examples of stored information include computer-useable instructions, data structures, program modules, and other data representations. Media examples include, but are not limited to, information-delivery media, RAM, ROM, EEPROM, flash memory or other memory technology, CD-ROM, digital versatile discs (DVD), holographic media or other optical disc storage, magnetic cassettes, magnetic tape, magnetic disk storage, and other magnetic storage devices. These technologies can store data momentarily, temporarily, or permanently. In an embodiment, non-transitory media are used.

The invention can be practiced in distributed-computing environments where tasks are performed by remote-processing devices that are linked through a communications network or other communication medium. In a distributed-computing environment, program modules can be located in both local and remote computer-storage media including memory storage devices. The computer-useable instructions form an interface to allow a computer to react according to a source of input. The instructions cooperate with other code segments or modules to initiate a variety of tasks in response to data received in conjunction with the source of the received data.

The present invention can be practiced in a network environment such as a communications network. Such networks are widely used to connect various types of network elements, such as routers, servers, gateways, and so forth. Further, the invention can be practiced in a multi-network environment having various, connected public and/or private networks.

Communication between network elements can be wireless or wireline (wired). As will be appreciated by those skilled in the art, communication networks can take several different forms and can use several different communication protocols.

Embodiments of the subject invention can be embodied in a processing system. Components of the processing system can be housed on a single computer or distributed across a network as is known in the art. In an embodiment, components of the processing system are distributed on computer-readable media. In an embodiment, a user can access the processing system via a client device. In an embodiment, some of the functions or the processing system can be stored and/or executed on such a device. Such devices can take any of a variety of forms. By way of example, a client device may be a desktop, laptop, or tablet computer, a personal digital assistant (PDA), an MP3 player, a communication device such as a telephone, pager, email reader, or text messaging device, or any combination of these or other devices. In an embodiment, a client device can connect to the processing system via a network. As discussed above, the client device may communicate with the network using various access technologies, both wireless and wireline. Moreover, the client device may include one or more input and output interfaces that support user access to the processing system. Such user interfaces can further include various input and output devices which facilitate entry of information by the user or presentation of information to the user. Such input and output devices can include, but are not limited to, a mouse, touch-pad, touch-screen, or other pointing device, a keyboard, a camera, a monitor, a microphone, a speaker, a printer, a scanner, among other such devices. As further discussed above, the client devices can support various styles and types of client applications.

All patents, patent applications, provisional applications, and publications referred to or cited herein are incorporated by reference in their entirety, including all figures and tables, to the extent they are not inconsistent with the explicit teachings of this specification.

It should be understood that the examples and embodiments described herein are for illustrative purposes only and that various modifications or changes in light thereof will be suggested to persons skilled in the art and are to be included within the spirit and purview of this application.

What is claimed is:

1. An apparatus, comprising:
a base;
a movable element, wherein the movable element is movably connected to the base such that the movable element can transition between at least two movable element positions; and
at least one hold element, wherein each of the at least one hold element is moveably connected to the base via a corresponding one or more hold element actuators, wherein the one or more hold element actuators of each hold element are configured such that the one or more hold element actuators can be driven to transition the corresponding hold element between at least two hold element positions, wherein the at least two hold element positions comprises a hold element hold position, wherein when one or more of the at least one hold element is in the hold element hold position movement of the movable element is limited.

2. The apparatus according to claim 1, wherein the at least two movable element positions comprises a movable element hold position, wherein when the movable element is in the movable element hold position, and the one or more of the at least one hold element is in the hold element hold position, movement of the movable element is limited.

3. The apparatus according to claim 2, wherein the moveable element is connected to the base via one or more movable element actuators, wherein the one or more movable element actuators can be driven to transition the moveable element between the at least two moveable element positions.

4. The apparatus according to claim 3, further comprising:
a controller, configured to drive the one or more moveable element actuators and the one or more hold element actuators corresponding to each of the at least one hold element,
wherein after the controller receives an off signal:
the controller drives the one or more movable element actuators to transition the moveable element to the moveable element hold position; and
the controller drives the one or more hold element actuators corresponding to each hold element of the at least one hold element to transition the hold element to the hold element hold position.

5. The apparatus according to claim 4, wherein after the controller receives an off signal:
the controller drives the one or more movable element actuators to transition the moveable element to the moveable element hold position; and
the controller drives the one or more hold element actuators corresponding to each hold element of the at least one hold element to transition the hold element to the hold element hold position.

6. The apparatus according to claim 1, wherein when one or more of the at least one hold element is in the hold element hold position movement of the movable element is prevented.

7. The apparatus according to claim 1, wherein when one or more of the at least one hold element is in the hold element hold position movement of the movable element is restricted to one or more desired moveable element positions of the at least two movable element positions.

8. The apparatus according to claim 1, wherein when one or more of the at least one hold element is in the hold element hold position movement of the movable element is restricted to a desired range of positions.

9. The apparatus according to claim 1, wherein when one or more of the at least one hold element is in the hold element hold position movement of the movable element past a certain point is prevented.

10. The apparatus according to claim 1, wherein when one or more of the at least one hold element is in the hold element hold position movement of the movable element in a certain direction is prevented.

11. The apparatus according to claim 1, wherein during a parked condition each of the at least one hold element is in the hold element hold position.

12. The apparatus according to claim 1, wherein the at least two hold element positions comprises a hold element free position, wherein when each of the at least one hold element is the hold element free position movement of the movable element is not limited by the at least one hold element.

13. The apparatus according to claim 12, wherein during a free condition each of the at least one hold element is in the hold element free position.

14. The apparatus according to claim 1, further comprising:
a controller, wherein the controller is configured to drive the one or more hold element actuators corresponding to each of the at least one hold element,
wherein after the controller receives an off signal the controller drives the one or more hold element actuators corresponding to each hold element of the at least one hold element to transition the hold element to the hold element hold position.

15. The apparatus according to claim 12, further comprising:
a controller, configured to drive the one or more hold element actuators corresponding to each of the at least one hold element,
wherein after the controller receives an on signal the controller drives the one or more hold element actuators corresponding to each hold element of the at least one hold element to transition the hold element to the hold element free position.

16. The apparatus according to claim 15, wherein after the controller receives the on signal the controller causes the moveable element to move relative to the base.

17. The apparatus according to claim 1, wherein the apparatus is a micromirror and the moveable element comprises a mirror plate.

18. The apparatus according to claim 1, wherein the moveable element comprises a lens holder.

19. The apparatus according to claim 1, wherein at least one hold element actuator of the one or more hold element actuators corresponding to each of the at least one hold element is a lateral bimorph actuator.

20. The apparatus according to claim 19, wherein the lateral bimorph actuator has an asymmetrical cross-section such that the lateral bimorph actuator moves in at least two dimensions when the lateral bimorph actuator is actuated.

21. The apparatus according to claim 1, wherein at least one hold element actuator of the one or more hold element actuators corresponding to each of the at least one hold element is a bistable thermal actuator.

22. The apparatus according to claim 1, wherein at least one hold element actuator of the one or more hold element actuators corresponding to each of the at least one hold element comprises a shape memory alloy (SMA), wherein the SMA actuates when heat is applied to the SMA and returns to a previous position when the heat dissipates.

23. The apparatus according to claim 1, wherein at least one hold element actuator of the one or more hold element actuators corresponding to each of the at least one hold element is a piezoelectric actuator.

24. A method for stabilizing an apparatus, comprising:
providing an apparatus, comprising:
a base;
a movable element, wherein the movable element is movably connected to the base such that the movable element can transition between at least two movable element positions; and
at least one hold element, wherein each of the at least one hold element is moveably connected to the base via a corresponding one or more hold element actuators, wherein the one or more hold element actuators of each hold element are configured such that the one or more hold element actuators can be driven to transition the corresponding hold element between at least two hold element positions, wherein the at least two hold element positions comprises a hold element hold position, wherein when one or more of the at least one hold element is in the hold element hold position movement of the movable element is limited;
receiving an off signal;
driving at least one of the one or more hold element actuators to transition the hold element to the hold element hold position.

25. The method according to claim 24, wherein the at least two movable element positions comprises a movable element hold position, wherein when the movable element is in the movable element hold position and the one or more of the at least one hold element is in the hold element hold position movement of the movable element is limited.

26. The method according to claim 25, wherein the moveable element is connected to the base via one or more movable element actuators, wherein the one or more movable element actuators can be driven to transition the moveable element between the at least two moveable element positions.

27. The method according to claim 26, further comprising:
driving at least one of the one or more moveable element actuators to transition the moveable element to the moveable element hold position.

28. The method according to claim 26, wherein the apparatus further comprises a controller configured to receive one or more signals and drive the one or more movable element actuators and drive the one or more hold element actuators in response to the one or more signals.

29. The method according to claim 28, further comprising:
Driving the at least one of the one or more moveable element actuators to transition the moveable element to the moveable element hold position via the controller.

30. The method according to claim 29, wherein the controller drives the at least one of the one or more moveable element actuators to transition the moveable element to the moveable element hold position when the controller receives an off signal.

31. The method according to claim 28, wherein the one or more signals comprises the movement signal, wherein the movement signal comprises a direction to move the moveable element, further comprising:
receiving the movement signal.

32. The method according to claim 31, further comprising:
driving via the controller at least one of the one or more moveable element actuators to move the moveable element in response to the movement signal.

33. The method according to claim 31, further comprising:
processing the movement signal via the controller after an off signal is received by the controller; and
determining not to drive the one or more moveable element actuators in response to the movement signal.

34. The method according to claim 24, wherein the at least two hold element positions comprises a hold element free position, wherein when one or more of the at least one hold element is the hold element free position movement of the movable element is not limited by the one or more of the at least one hold element.

35. The method according to claim 34, further comprising:
receiving an on signal;
driving at least one of the one or more hold element actuators to transition the hold element to the hold element free position.

36. The method according to claim 24, wherein the apparatus is a micromirror and the moveable element comprises a mirror plate.

37. The method according to claim 24, wherein the moveable element comprises a lens holder.
